(19) United States
(12) Patent Application Publication
(10) Pub. No.: US 2008/0303127 A1
(43) Pub. Date: Dec. 11, 2008

(54) CAP-LESS PACKAGE AND MANUFACTURING METHOD THEREOF

(75) Inventor: Junji Fujino, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/125,477

(22) Filed: May 22, 2008

(30) Foreign Application Priority Data
Jun. 5, 2007 (JP) 2007-149542
Mar. 31, 2008 (JP) 2008-091851

(51) Int. Cl. H01L 23/495; H01R 43/00

(52) U.S. Cl. 257/676; 29/827; 257/E23.036

(57) ABSTRACT

A cap-less package comprises: a metallic die pad part; a submount mounted on the die pad part; an optical semiconductor element mounted on the submount; an insulating member fixed to the die pad part; a lead electrode inserted in the insulating member; and a wire connecting the lead electrode to the semiconductor optical element, wherein the submount, the optical semiconductor element, a portion of the lead electrode closer to the optical semiconductor element than to the insulating member, and the wire are located opposite the die pad part.

### BACKGROUND OF THE INVENTION

1. Field of the Invention

The present invention relates to a cap-less package mounted with a laser diode which is not covered with any cap and a manufacturing method thereof.

2. Background Art

A stem used in a general laser diode package is made up of a metal member having a circular eyelet part and a block-like die pad part. A lead electrode is inserted into a hole formed in the eyelet part and glass-sealed (e.g., see Patent Document 1).

Such a metal member is often manufactured by forging. However, since the shape of the metal member is complicated, the life of the metal die used for manufacturing is short, which drives up the manufacturing cost. Furthermore, after assembling the whole unit including the lead electrode, a plating film needs to be formed over the entire package surface in a complicated shape. For this reason, there are concerns about cost increases accompanying a steep cost rise of precious metals.

Furthermore, a stem compatible package in which an eyelet part and resin base are bonded together is used (e.g., see Patent Documents 2 to 7). In such a package, a lead electrode is inserted in a resin base. A die pad part mounted with a laser diode is formed by being bonded to the eyelet part or by folding the eyelet part.

### [Patent Document 1] Japanese Patent Laid-Open No. 07-335980

### [Patent Document 2] Japanese Patent Laid-Open No. 2002-324934

### [Patent Document 3] Japanese Patent Laid-Open No. 04-23383

### [Patent Document 4] Japanese Utility Model Laid-Open No. 63-170978

### [Patent Document 5] Japanese Utility Model Laid-Open No. 63-178344

### [Patent Document 6] Japanese Patent Laid-Open No. 09-205251

### [Patent Document 7] Japanese Patent Laid-Open No. 2000-252575

### SUMMARY OF THE INVENTION

The packages in Patent Documents 2 to 7 are premised on sealed packaging using a cap. Therefore, when these package structures are applied to cap-less packages which are mainstream in recent years, since the laser diode and wires are not mechanically protected, there is a problem that the laser diode and wires are liable to be damaged by contact with outside parts.

Furthermore, there are cases where a bonding agent for fixing the resin base and metal cover are damaged by heat or pressure or cases where when applied to a cap-less package, the resin base and metal cover are degraded, deformed and peeled off due to moisture in the atmosphere.

Furthermore, the back of the eyelet part is covered with the resin base and the metal part is not exposed. For this reason, when the eyelet part is sandwiched between metal heat dissipation blocks and heated in a burn-in step, heat cannot be dissipated enough. Furthermore, when the eyelet part is sandwiched between heater blocks and heated in a die bonding step, the eyelet part cannot be heated abruptly, resulting in a problem that productivity cannot be secured.

The present invention has been implemented to solve the aforementioned problems and it is a first object of the present invention to provide a cap-less package capable of preventing a laser diode or wires from being damaged while suppressing increases in the number of parts and cost. It is a second object of the present invention to provide a cap-less package capable of fixing a metal member that forms a die pad part and an insulating member without using any bonding agent. It is a third object of the present invention to provide a cap-less package capable of securing a heat path during heat dissipation or heating.

According to one aspect of the present invention, a cap-less package comprises: a metallic die pad part; a submount mounted on the die pad part; an optical semiconductor element mounted on the submount; an insulating member fixed to the die pad part; a lead electrode inserted in the insulating member; and a wire for connecting the lead electrode and the laser diode, wherein the submount, the optical semiconductor element, a portion of the lead electrode closer to the optical semiconductor element side than the insulating member and the wire exist in an area above the die pad part.

The cap-less package according to the present invention can prevent damages to the laser diode and wires while suppressing increases in the number of parts and cost.

Other and further objects, features and advantages of the invention will appear more fully from the following description.

### BRIEF DESCRIPTION OF THE DRAWINGS

FIG. 1 is a perspective view of a cap-less package according to Embodiment 1 of the present invention.

FIG. 2 is a perspective view showing a cap-less package according to Embodiment 2 of the present invention.

FIG. 3 is a front view showing the cap-less package according to Embodiment 2 of the present invention.

FIG. 4 is a rear showing the cap-less package according to Embodiment 2 of the present invention.

FIG. 5 shows a relationship between the aperture diameter of a heat dissipation block and maximum output of the laser diode.

FIG. 6 shows an experiment.

FIG. 7 is a perspective view showing a cap-less package according to Embodiment 3 of the present invention.

FIG. 8 is a perspective view showing a cap-less package according to Embodiment 4 of the present invention.

FIGS. 9-12 are perspective views for explaining a method of manufacturing a cap-less package according to Embodiment 5 of the present invention.

### DETAILED DESCRIPTION OF THE PREFERRED EMBODIMENTS

### Embodiment 1

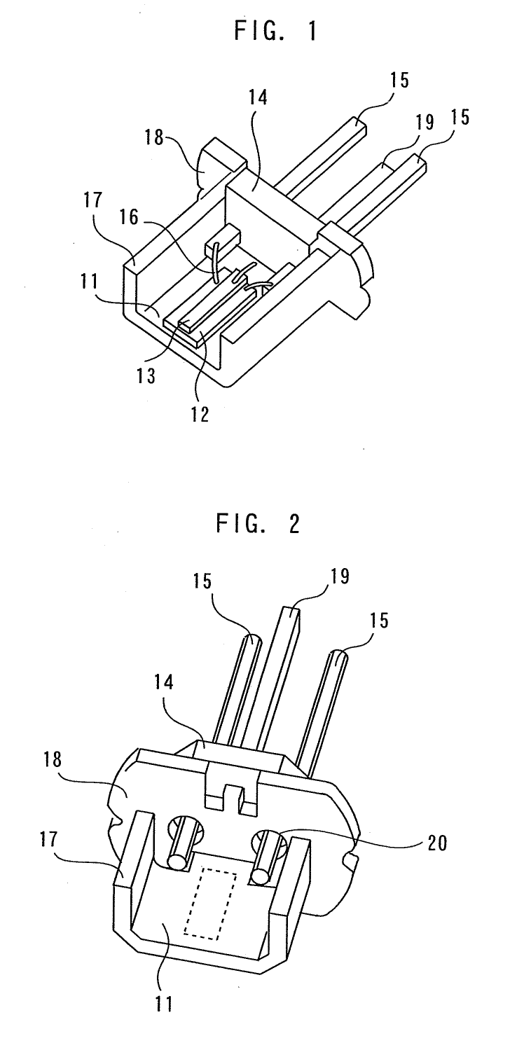

FIG. 1 is a perspective view of a cap-less package according to Embodiment 1 of the present invention. A submount 12 is mounted on a metallic die pad part 11 by means of AuSn solder (not shown). A laser diode 13 (optical semiconductor element) is mounted on the submount 12 by means of AuSn solder (not shown). The laser diode 13 is a red semiconductor laser and has an outside dimension of 0.2 mm×1.5 mm and a thickness of 0.1 mm. The submount 12 is made of AlN and has an outside dimension of 0.6 mm×1.5 mm and a thickness of 0.2 mm.

A glass-epoxy substrate 14 (insulating member) having a thickness of 0.8 mm is fixed to the die pad part 11 and a stem compatible package is formed. Signaling lead electrodes 15 (lead electrode) are inserted in the glass-epoxy substrate 14. The signaling lead electrode 15 is made of Cu, has a cross section of 0.4 mm per side and the surface thereof is Ni/Au-plated. The laser diode 13 is connected to the signaling lead electrodes 15 and die pad part 11 via wires 16.

According to this embodiment, the submount 12, laser diode 13, portion of the signaling lead electrodes 15 closer to the laser diode 13 than the glass-epoxy substrate 14 and wires 16 exist in the area above the die pad part 11. Furthermore, protective walls 17 are formed on both sides of the die pad part 11 to protect the laser diode 13 and wires 16. This allows even the cap-less package to protect the laser diode 13 and wires 16 and prevent damages. Being a cap-less package, this package allows heat dissipation using the wind produced by rotation of a medium.

Furthermore, by applying press stamping and folding to the Cu lead frame having a thickness of 0.4 mm, the die pad part 11, eyelet part 18, protective walls 17 and grounding lead electrode 19 (electrode) are formed as a single piece made of the same metal member. This makes it possible to suppress the number of parts and a cost increase.

Furthermore, the grounding lead electrode 19 is inserted in the glass-epoxy substrate 14 to fasten the eyelet part 18. This allows the die pad part 11 and the glass-epoxy substrate 14 to be fixed without using any bonding agent or the like.

Here, Cu is used for the die pad part 11 and signaling lead electrodes 15, but metal members for other general electronic parts such as an Fe group or 42 alloy. Furthermore, Ag plating or plating for electronic parts such as Ni/Pd/Au may be applied to the surface of the signaling lead electrodes 15 instead of Ni/Au plating. Furthermore, the cross section of the signaling lead electrode 15 may be a circular cross section instead of a rectangular cross section. Furthermore, the grounding lead electrode 19 may also be formed of a member different from that of the die pad part 11 or the like. Furthermore, the laser diode 13 may be a blue laser or two-wavelength chip or the like. Furthermore, the material of the submount 12 is not limited to AlN but the material may be SiC or alumina. Furthermore, when the die pad part 11 or the like is formed, the Cu lead frame may be molded by not only stamping but also etching.

### Embodiment 2

FIG. 2 is a perspective view showing a cap-less package according to Embodiment 2 of the present invention. This embodiment is the same as Embodiment 1 except in the shape of the eyelet part 18. A laser diode 13 and a submount 12 are mounted in the area marked by a dotted line, but illustration thereof is omitted here.

In this embodiment, an eyelet part 18 is formed integral with a die pad part 11 and protective walls 17 using the same metal member. This can reduce the number of parts. Furthermore, since the resistance of the junction interface between the die pad part 11 and eyelet part 18 is reduced, the heat dissipation property can be improved. Furthermore, the eyelet part 18 has a plane perpendicular to the die pad part 11 and a glass-epoxy substrate 14 is overlapped on this plane. Moreover, part of the outside shape of the eyelet part 18 is arc-shaped. Furthermore, through holes 20 for signaling lead electrodes 15 are formed in the eyelet part 18.

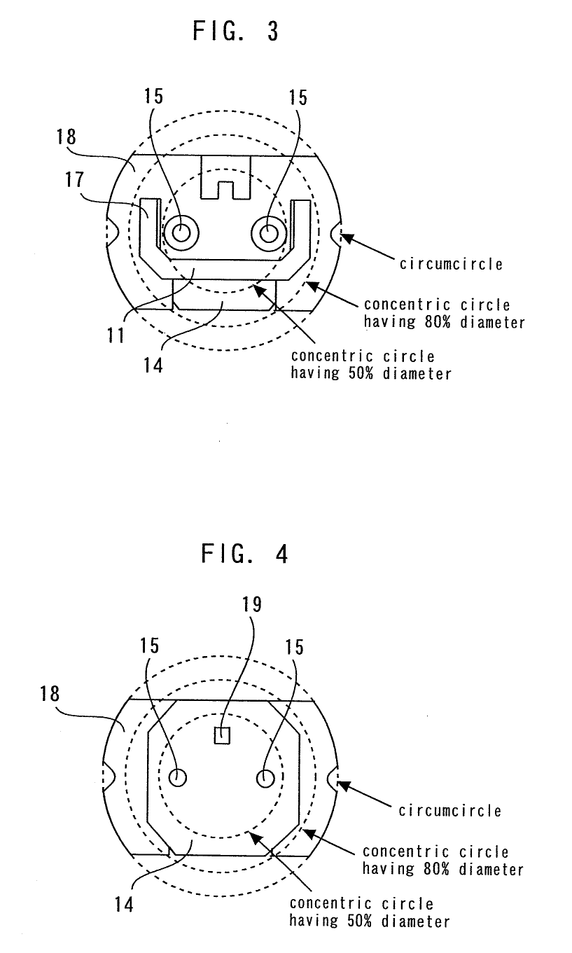

FIG. 3 is a front view showing the cap-less package according to Embodiment 2 of the present invention and FIG. 4 is a rear view. The figures show a circumcircle of the eyelet part 18, and a circle concentric with this circumcircle and having a diameter 80% of the diameter of the circumcircle (concentric circle having 80% diameter) and a circle having a diameter 50% of the diameter of the circumcircle (concentric circle having 50% diameter) with dotted lines.

Since the signaling lead electrodes 15 exist inside the 50% diameter concentric circle, this portion cannot be used as a heat path during heat dissipation or heating. On the other hand, the die pad part 11, protective walls 17 and glass-epoxy substrate 14 do not exist outside the 80% diameter concentric circle. Therefore, since both sides of the eyelet part 18 are exposed outside the 80% diameter concentric circle, the heat path can be secured during heat dissipation such as burn-in or during heating such as die bonding.

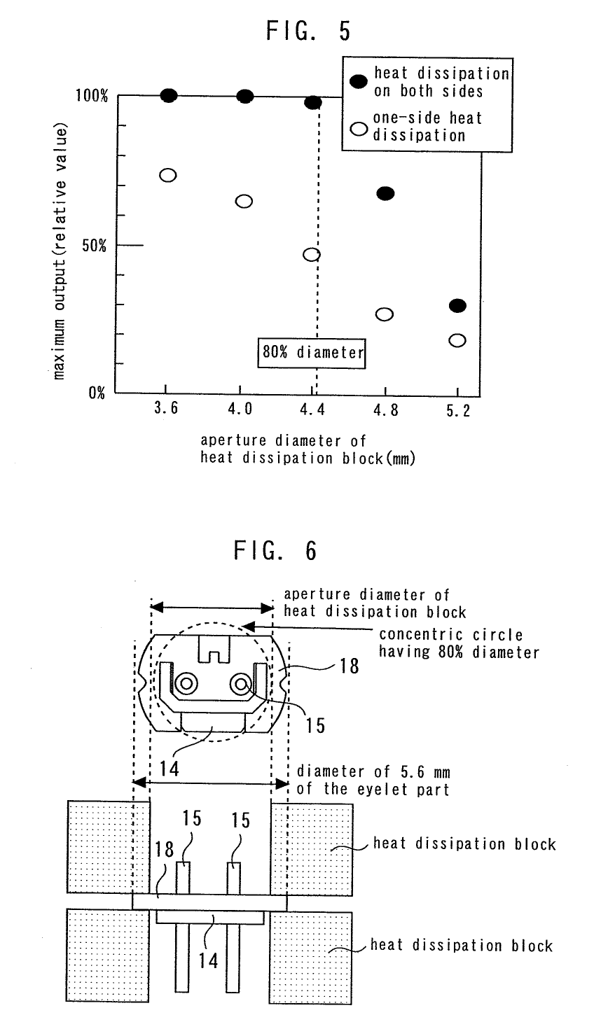

FIG. 5 shows a relationship between the aperture diameter of a heat dissipation block and maximum output of the laser diode. Here, as shown in FIG. 6, an experiment was conducted with the outer perimeter of the eyelet part 18 sandwiched by the heat dissipation blocks on the back and front. The diameter of the circumcircle of the eyelet part 18 is 5.6 mm. This experiment result shows that even when the diameter of the heat dissipation block aperture is 4.4 mm (80% of diameter of eyelet part 18), the maximum output with one-side heat dissipation is reduced to half or less. On the other hand, it is appreciated that the maximum output does not substantially degrade if the outside part of the concentric circle having a diameter of 4.4 mm of the eyelet part 18 can be used for heat dissipation on both sides.

It is preferable to make rectilinear the upper and lower parts of the eyelet part 18 and glass-epoxy substrate 14 and make the width in the vertical direction of the glass-epoxy substrate 14 greater than or equal to the width of the eyelet part 18. This allows the glass-epoxy substrate 14 to be handled as a connected sheet with V-groove cuts and perforations during package manufacturing and allows productivity to be improved when fixed to the eyelet part 18 or when the signaling lead electrodes 15 are inserted or the like. Furthermore, the glass-epoxy substrate 14 may also be rectangular, a shape with four rounded corners or a shape with inward curved notches instead of being octagonal.

### Embodiment 3

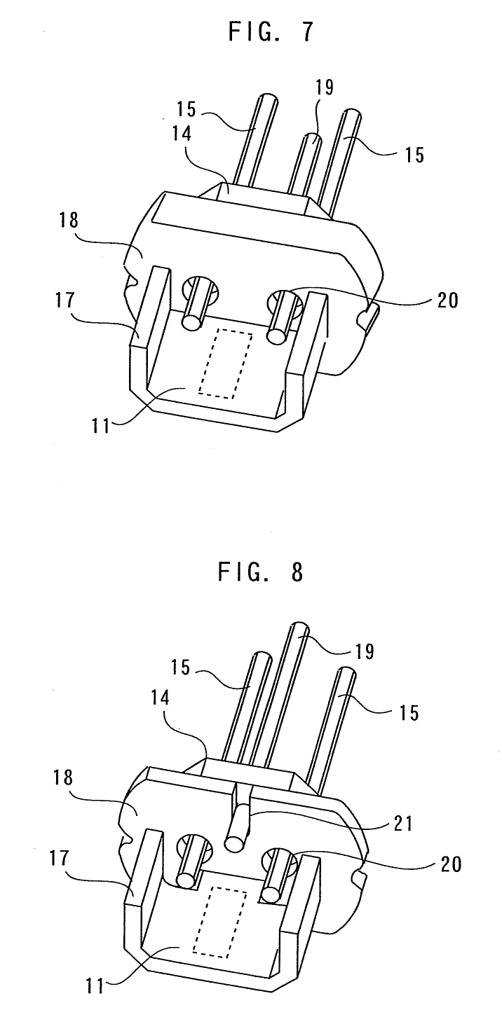

FIG. 7 is a perspective view showing a cap-less package according to Embodiment 3 of the present invention. In this embodiment, an eyelet part 18 is made of a metal member different from that of a die pad part 11 and protective walls 17. This makes it possible to increase the thickness of the eyelet part 18 and increase thermal capacity. The rest of the configuration is the same as that of Embodiment 2.

The eyelet part 18 is electrically and thermally connected to the metal member forming the die pad part 11 and protective walls 17 by a pressure when the grounding lead electrode 19 is inserted into the glass-epoxy substrate 14. However, use of brazing or soldering or ultrasound pressure welding or conductive bonding agent allows a more reliable connection.

### Embodiment 4

FIG. 8 is a perspective view showing a cap-less package according to Embodiment 4 of the present invention. A notch 21 having a width approximate to the diameter of a grounding lead electrode 19 is formed in an eyelet part 18. Engaging the grounding lead electrode 19 with this notch 21 allows both parts to be fixed and made electrically continuous. The rest of the configuration is the same as that of Embodiment 2.

Furthermore, an aperture having a width approximate to the diameter of the grounding lead electrode 19 may also be formed in the eyelet part 18 instead of the notch 21. Alternatively, an aperture slightly greater than the diameter of the grounding lead electrode 19 may be formed in the eyelet part 18 and the flanged grounding lead electrode 19 may be inserted or the projecting part of the grounding lead electrode 19 may be deformed by a pressure or the like.

### Embodiment 5

Manufacturing steps of a cap-less package according to Embodiment 5 of the present invention will be explained using the attached drawings.

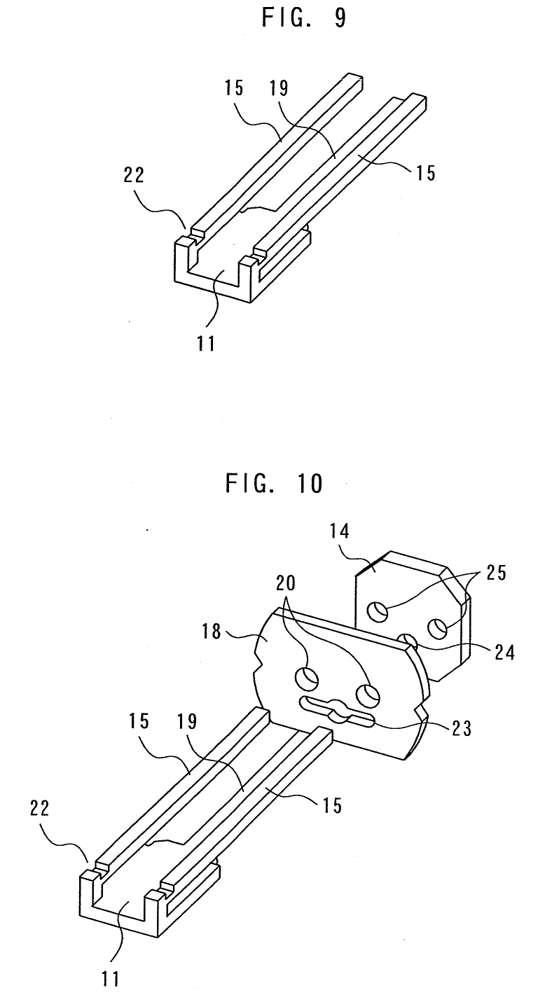

First, a die pad part 11, grounding lead electrode 19 and signaling lead electrodes 15 are formed as a single piece using the same metal member as shown in FIG. 9 through press stamping and folding on a Cu lead frame having a thickness of 0.4 mm. Notches 22 are then formed at the joints between the signaling lead electrodes 15 and die pad part 11.

Next, as shown in FIG. 10, the grounding lead electrode 19 is inserted into a slit 23 of the eyelet part 18 and a through hole 24 of a glass-epoxy substrate 14 and the signaling lead electrodes 15 are inserted into through holes 20 of the eyelet part 18 and through holes 25 of the glass-epoxy substrate 14 and the die pad part 11 is engaged with the slit 23 of the eyelet part 18. This causes the die pad part 11 and eyelet part 18 to be electrically and thermally connected.

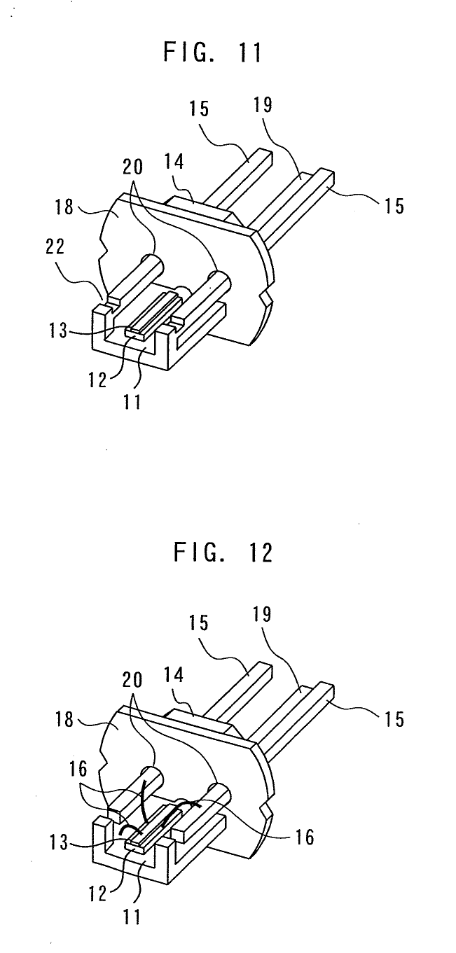

Next, as shown in FIG. 11, a submount 12 and laser diode 13 are mounted on the die pad part 11. As shown in FIG. 12, the laser diode 13, signaling lead electrodes 15 and die pad part 11 are connected via wires 16. The notches 22 are then cut by means of laser cutting and the signaling lead electrodes 15 are electrically separated from the die pad part 11. The cap-less package according to this embodiment is manufactured in these steps.

Adopting the configuration whereby the die pad part 11 is engaged with the slit of the eyelet part 18 makes it possible to use metal plates for the die pad part 11 and eyelet part 18, thereby realize a cost reduction and secure a heat dissipation path connecting both parts.

Furthermore, by forming the die pad part 11 and signaling lead electrodes 15 as a single piece using the same metal member, mounting both parts on the glass-epoxy substrate 14 and then separating the one from the other, the mounting of the die pad part 11 and signaling lead electrode 15 on the glass-epoxy substrate 14 is completed at a time, and it is thereby possible to reduce cost and improve productivity.

Cutting of the notches 22 may be performed before wire bonding. Cutting of the notches 22 is not limited to laser cutting but may also be performed using other methods such as press cutting using a metal die. Bonding the die pad part 11 and eyelet part 18 by means of brazing, soldering, ultrasonic pressure welding or conductive bonding agent allows a more reliable connection of both parts.

Furthermore, this embodiment achieves a cost reduction by applying wire bonding to the press cutting surface of the original metal member of the signaling lead electrodes 15. However, the signaling lead electrode 15 may be bent by 90° and wire bonding may be applied to the same surface as that of the die pad part 11 of the original metal member.

Furthermore, this embodiment uses the die pad part 11, signaling lead electrodes 15 and eyelet part 18 subjected to desired plating (surface metallizing). However, plating may be applied after completing assembly up to the stage in FIG. 12 by taking advantage of the fact that the die pad part 11 and signaling lead electrodes 15 are electrically connected at the notches 22 and the die pad part 11 and the eyelet part 18 are electrically connected at the slit 23. In this way, a cost reduction can be achieved.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2007-149542, filed on Jun. 5, 2007 and a Japanese Patent Application No. 2008-091851, filed on Mar. 31, 2008 including specification, claims, drawings and summary, on which the Convention priority of the present application is based, are incorporated herein by reference in its entirety.

1. A cap-less package comprising:
a metallic die pad part;
a submount mounted on the die pad part;
an optical semiconductor element mounted on the submount;
an insulating member fixed to the die pad part;
a lead electrode partially within the insulating member; and
a wire connecting the lead electrode to the optical semiconductor element, wherein the submount, the optical semiconductor element, a portion of the lead electrode closer to the optical semiconductor element than to the insulating member, and the wire are located in an area opposite the die pad part.

2. The cap-less package according to claim 1, further comprising protective walls located on opposite sides of the die pad part as a single piece of the same metal member as the die pad parts to protect the optical semiconductor element and the wire.

3. The cap-less package according to claim 1, further comprising an electrode that is a single piece of the same metal member as the die pad part and partially within the insulating member.

4. The cap-less package according to claim 1, further comprising a metallic eyelet part lying in a plane perpendicular to the die pad part, the insulating member overlapping the plane, wherein the die pad part, the protective walls, and the insulating member are located only inside a circle which is concentric with a circumference of the eyelet part and has a diameter 80% of the diameter of the circumference.

5. The cap-less package according to claim 1, further comprising a metallic eyelet part lying in a plane perpendicular to the die pad part, the insulating member overlapping the plane, wherein
the eyelet part comprises a slit, and
the die pad part is engaged with the slit of the eyelet part.

6. A method of manufacturing the cap-less package according to claim 1, comprising:
forming the lead electrode as a single piece of the same metal member as the die pad part;
forming notches at a joint between the lead electrode and the die pad part; and
fixing the insulating member to the die pad part, inserting the lead electrode into the insulating member, and then cutting the notches.
